(19) United States
(12) Patent Application Publication
(10) Pub. No.: US 2020/0149149 A1
(43) Pub. Date: May 14, 2020

(54) MASK AND VAPOR DEPOSITION DEVICE

(71) Applicant: Yungu (Gu'an) Technology Co., Ltd., Langfang (CN)

(72) Inventors: Xiaopeng LV, Langfang (CN); Weili LI, Langfang (CN); Lu ZHANG, Langfang (CN); Jingjing ZHAO, Langfang (CN); Ya WANG, Langfang (CN); Shuaiyan GAN, Langfang (CN)

(21) Appl. No.: 16/742,933

(22) Filed: Jan. 15, 2020

Related U.S. Application Data
(63) Continuation of application No. PCT/CN2019/074099, filed on Jan. 31, 2019.

(30) Foreign Application Priority Data
Jul. 27, 2018 (CN) 201810843949.6

(51) Int. Cl. C23C 14/04; C23C 14/24; H01L 51/00; H01L 51/56

(52) U.S. Cl. CPC C23C 14/042; H01L 51/56; H01L 51/0011; C23C 14/24

(57) ABSTRACT

The application relates to a mask and a vapor deposition device. The mask includes a first region provided with a first plurality of openings; and second regions located at both sides of the first region along a predetermined direction. At least one of the second regions is provided with a third plurality of openings disposed adjacent to the first plurality of openings and having a same structure as the first plurality of openings. At least a part of the first plurality of openings are used to form a first type of sub-pixels when the mask is in a first state. The first plurality of openings and at least a part of the third plurality of openings are used together to form a type of sub-pixels different from the first type of sub-pixels, when the mask moves a predetermined distance along the predetermined direction to be in a second state.

### CROSS-REFERENCES TO RELATED APPLICATIONS

The application is a continuation of International Application No. PCT/CN2019/074099, filed on Jan. 31, 2019, which claims the benefit of priority to Chinese Patent Application No. 201810843949.6, filed on Jul. 27, 2018, both of which are incorporated herein by reference in their entireties.

### TECHNICAL FIELD

The application relates to the field of display technology.

### BACKGROUND

An Organic Light-Emitting Diode (OELD) is also known as an Organic Electroluminescence Display. An OELD display panel is made of a substrate and a very thin coating of organic materials. When an electric current passes through the organic materials, the organic materials will emit light. The OLED display panel includes a plurality of light-emitting pixel elements arranged in a matrix structure. For a colored OLED, each light-emitting pixel element generally includes sub-pixels of three colors: red R, green G, and blue B.

### SUMMARY

The application is to provide a mask and a vapor deposition device.

In an aspect, embodiments of the application provide a mask including a first region provided with a first plurality of openings; and second regions located at both sides of the first region along a predetermined direction, wherein at least one of the second regions is provided with a third plurality of openings, and the third plurality of openings are disposed adjacent to the first plurality of openings and have a same structure as the first plurality of openings. At least a part of the first plurality of openings are used to form a first type of sub-pixels when the mask is in a first state. The first plurality of openings and at least a part of the third plurality of openings are used together to form a type of sub-pixels different from the first type of sub-pixels, when the mask moves a predetermined distance along a predetermined direction to be in a second state.

In another aspect, the embodiments of the application further provide a vapor deposition device including the mask as described above.

In yet another aspect, the embodiments of the application further provide a vapor deposition method by use of a mask. The mask includes a first region provided with a first plurality of openings and second regions located at both sides of the first region along a predetermined direction. At least one of the second regions is provided with a third plurality of openings, and the third plurality of openings are disposed adjacent to the first plurality of openings and have a same structure as the first plurality of openings. The vapor deposition method includes forming a first type of sub-pixels by use of at least a part of the first plurality of openings when the mask is in a first state; moving the mask a predetermined distance along the predetermined direction to place the mask in a second state; and forming a type of sub-pixels different from the first type of sub-pixels by use of the first plurality of openings and at least a part of the third plurality of openings together when the mask is in the second state.

With the mask and the vapor deposition device provided in the embodiments of the application, the first plurality of openings for forming sub-pixels of any color are disposed in the first region of the mask, and the third plurality of openings having the same structure as the first plurality of openings are disposed in at least one second region along the predetermined direction, so that the vapor deposition for sub-pixels of at least two colors can be realized by just moving the mask a predetermined distance. As such, an undesirable risk such as color mixing can be avoided and the vapor deposition effect and efficiency of the mask can be improved.

### BRIEF DESCRIPTION OF THE DRAWINGS

The application can be better understood from the following description of specific embodiments of the application with reference to the accompanying drawings, in which:

Other features, objects, and advantages of the application will become more apparent by reading the following detailed description of non-limiting embodiments with reference to the accompanying drawings, in which the same or similar reference numerals represent the same or similar features.

FIG. 1 is a schematic diagram of pixel arrangement of an OLED display panel in a first embodiment of the application.

FIG. 2 is a schematic structural diagram of a mask provided in the first embodiment of the application;

FIG. 3 is a schematic diagram of a moving process of the mask shown in FIG. 2 during vapor deposition for sub-pixels of different colors;

FIG. 4 is a schematic diagram of pixel arrangement of an OLED display panel in a second embodiment of the application.

FIG. 5 is a schematic structural diagram of a mask provided in the second embodiment of the application;

FIG. 6 is a schematic diagram of a moving process of the mask shown in FIG. 5 during vapor deposition for sub-pixels of different colors;

FIG. 7 is a schematic diagram of pixel arrangement of an OLED display panel in a third embodiment of the application.

FIG. 8 is a schematic structural diagram of a mask provided in the third embodiment of the application;

FIG. 9 is a schematic diagram of a moving process of the mask shown in FIG. 8 during vapor deposition for sub-pixels of different colors;

FIG. 10 is a schematic structural diagram of a mask provided in a fourth embodiment of the application;

FIG. 11 is a schematic diagram of a moving process of the mask shown in FIG. 10 during vapor deposition for sub-pixels of different colors.

### DETAILED DESCRIPTION OF THE INVENTION

Generally, a metal material mask is used to control a coating position of the organic materials on the substrate. Since the R/G/B color sub-pixels of the OLED display panel are formed by vapor deposition using organic light-emitting materials of different colors, a mask is needed for each of the R/G/B color sub-pixels to vapor deposit an organic material of a corresponding color respectively. For example, after the vapor deposition for the R color sub-pixels is completed, the mask corresponding to the color R is removed and then the mask corresponding to the color G is installed for the vapor deposition for the G color sub-pixels; after the vapor deposition for the G color sub-pixels is completed, the mask corresponding to the color G is removed and then the mask corresponding to the color B is installed for the vapor deposition for the B color sub-pixels. During this vapor deposition process, the vapor deposition device is opened multiple times, and impurities such as dust and the like may be easily mixed onto the substrate, which seriously affects the coating effect of the organic light-emitting material layer.

Example embodiments will be more fully described with reference to the accompanying drawings.

### First Embodiment

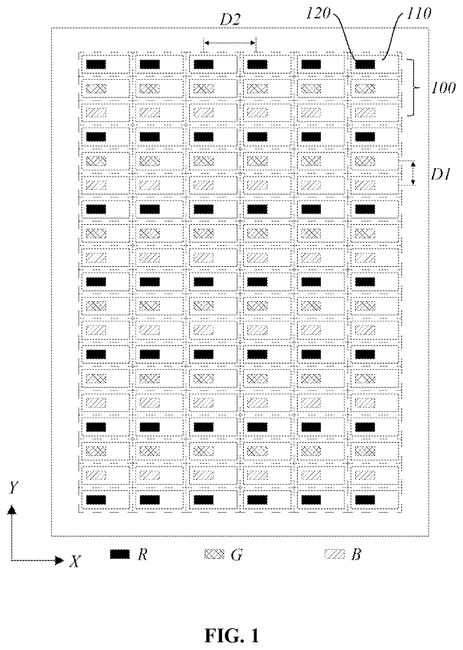

FIG. 1 is a schematic diagram of pixel arrangement of an OLED display panel in the first embodiment of the application.

Referring to FIG. 1, the OLED display panel includes a plurality of groups of light-emitting pixel elements 100 arranged in a matrix structure along a first direction X and a second direction Y. Each group of light-emitting pixel elements 100 include sub-pixels 110 of N colors, where N≥3. The sub-pixels 110 of each color includes an organic light-emitting material layer 120. The organic light-emitting material layer of the sub-pixels 110 of each color is formed by vacuum evaporation coating with an organic material of a corresponding color. The sub-pixels include, but are not limited to, sub-pixels of three colors: red R, green G, and blue B. Taking the sub-pixels of three colors R/G/B as an example, in the OLED display panel, each line of sub-pixels 110 along the first direction X have a same color, and a distance between two adjacent sub-pixels 110 along the second direction Y is D1, and a distance between two adjacent sub-pixels 110 along the first direction X is D2.

For the OLED display panel, a mask is used to control the coating positions of organic materials of different colors on the substrate. The mask is generally made of INVAR and has a thickness of 20-40 μm. INVAR is a nickel-iron alloy which has a very low thermal expansion coefficient and can maintain a fixed length over a wide temperature range. During the vapor deposition, the mask is placed between the substrate and the vapor deposition device, and organic light-emitting materials of corresponding colors are placed in the vapor deposition device for vapor deposition for sub-pixels 110 of different colors on the substrate.

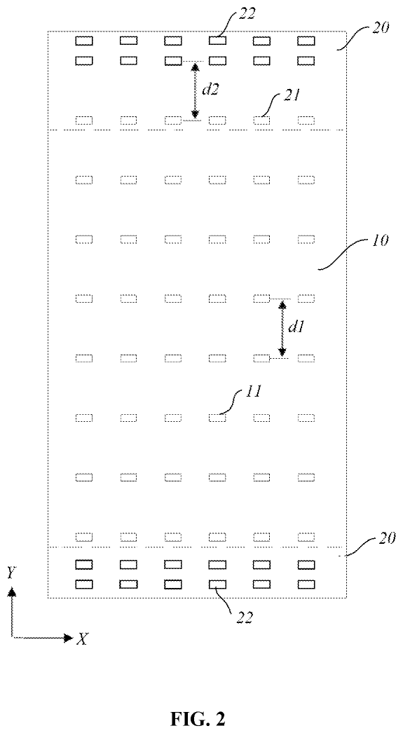

FIG. 2 is a schematic structural diagram of a mask provided in the first embodiment of the application.

Referring to FIG. 2, in the embodiment of the application, a mask is provided. The mask includes a first region 10 and second regions 20. The second regions 20 are located at both sides of the first region 10 along a predetermined direction.

As shown by the dashed box in FIG. 2, the first region 10 is provided with a plurality of first openings 11 distributed along the first direction X and the second direction Y perpendicular to each other. The plurality of first openings 11 are disposed respectively corresponding to sub-pixels of any color of the plurality of groups of light-emitting pixel elements, so as to form the sub-pixels of any color.

In order to ensure a dimensional machining accuracy of the first openings 11, the second regions 20 are generally provided as a buffer at both sides of the first region 10 of the mask along the predetermined direction. A plurality of third openings 21 are disposed in one of the second regions 20. The third openings 21 are disposed adjacent to the first openings 11 and have the same structure as the first openings 11. That is, the shapes, sizes, and machining accuracies of the third openings 21 are all the same as those of the first openings 11.

In a first state, at least a part of the plurality of first openings 11 may be used to form a first type of sub-pixels. In a second state, the mask is moved a predetermined distance along the predetermined direction, and the plurality of the first openings 11 and at least a part of the plurality of third openings 21 are used together to form a type of sub-pixels different from the first type of sub-pixels. The type of sub-pixels different from the first type of sub-pixels are another type of sub-pixels having a color different from the color of the first type of sub-pixels. Thus, the vapor deposition for the sub-pixels of at least two colors can be completed by moving the mask the predetermined distance along the predetermined direction.

In the mask provided in the embodiment of the application, the plurality of first openings 11 for forming sub-pixels of any color are disposed in the first region 10 of the mask, and the plurality of third openings 21 having the same structure as the first openings 11 are disposed in at least one second region 20 along the predetermined direction, so that the vapor deposition for the sub-pixels of at least two colors can be realized by just moving the mask the predetermined distance without necessity of removing the mask during the vapor deposition process. As such, impurities such as dust and the like can be prevented from being mixed onto the substrate, the effect and efficiency of the vapor deposition can be improved, and the structure is simple and the cost is low.

The specific structure of the mask provided in the embodiment of the application will be described in detail below with reference to the drawings.

Referring again to FIG. 2, the plurality of third openings 21 in the second region 20 are arranged in the same manner as the arrangement of the plurality of first openings 11, and the plurality of third openings 21 are arranged in M lines along a direction at a predetermined angle from the predetermined direction, where M is an integer and M≥1.

Further, the plurality of first openings 11 and the plurality of third openings 21 are arranged in lines along a direction perpendicular to the predetermined direction. In the first region 10 and the second regions 20, a first distance d1 along the predetermined direction between two adjacent first openings 11, a first distance d1 between two adjacent third openings 21 and a first distance d1 between a first opening 11 and a third opening 21 adjacent to the first opening 11 all satisfy Equation (1):

d1=N×L (1)

Here, L is the predetermined distance the mask moves along the predetermined direction. When the predetermined direction is the second direction Y, L is the distance D1 along the second direction Y between two adjacent sub-pixels 110; when the predetermined direction is the first direction X, L is the distance D2 along the first direction X between two adjacent sub-pixels 110.

As mentioned above, the second regions 20 serve as a process buffer for the first region 10, and each second region 20 is further provided with second openings 22 aligned in rows and columns along the first direction X and the second direction Y. A plurality of second openings 22 in at least one second region 20 are disposed at a side of the plurality of corresponding third openings 21 along the predetermined direction. There are at least two lines of second openings 22 in each second region 20, and the machining accuracy of the second openings 22 is lower than the machining accuracy of the first openings 11. The shapes and sizes of the second openings 22 may be the same as or different from the shapes and sizes of the first openings 11.

Since the dimensional machining accuracy of the second opening 22 is lower than the dimensional machining accuracy of the first opening 11, an inner edge of the second opening 22 is rough, and organic materials of different colors may remain on the rough edge of the second opening 22 during vapor deposition. As a result, there may be an undesirable risk such as color mixing, and thus the second openings 22 cannot be used for vapor deposition.

In addition, when the plurality of third openings 21 are arranged in a line, an overall size of the mask is minimal. In order to complete the vapor deposition for multi-color sub-pixels, in the second region 20, a second distance d2 along the predetermined direction between a third opening 21 and a second opening 22 adjacent to the third opening 21 satisfies d2≥d1.

In order to reduce the manufacturing cost of the mask, during pixel typesetting, pattern sizes of the openings corresponding to two colors R and G on the mask are generally designed to be a same size, and then the vapor deposition for the sub-pixels of the two colors can be completed by moving the mask the predetermined distance along the predetermined direction. In some cases, pattern sizes of the openings corresponding to multiple colors such as R, G, B and the like may be also designed to be a same size, and then the vapor deposition for the sub-pixels of the multiple colors can be completed by successively moving the mask the predetermined distance along the predetermined direction.

For the convenience of description, the embodiment of the application is illustrated with reference to an example in which the pattern sizes of the openings corresponding to three colors R, G, and B are designed to be a same size.

In FIG. 2, the plurality of first openings 11 in the first region 10 are disposed respectively corresponding to sub-pixels of any color of the plurality of groups of light-emitting pixel elements, such as red sub-pixels. The predetermined direction is the second direction Y, and the second regions 20 are located at both sides of the first region 10 along the second direction Y.

The plurality of first openings 11 in the first region 10 and the plurality of third openings 21 in one of the second regions 20 are aligned in rows and columns along the first direction X and the second direction Y, and the plurality of third openings 21 are distributed in a line in the second direction Y. In the first region 10 and the second regions 20, a first distance d1 along the second direction Y between two adjacent first openings 11, a first distance d1 along the second direction Y between two adjacent third openings 21 and a first distance d1 along the second direction Y between a first opening 11 and a third opening 21 adjacent to the first opening 11 all satisfy d1=3×D1, and a second distance d2 along the second direction Y between a third opening 21 and a second opening 22 adjacent to the third opening 21 in one of the second regions 20 satisfies d2≥d1, so that the vapor deposition for the sub-pixels of at least two colors can be realized.

Further, the shape of the first opening 11 corresponds to the shape of the organic light emitting material layer 120 of the sub-pixel 110, and the size of the first opening 11 is larger than the size of the organic light emitting material layer 120. In addition, the shape of the first opening 11 may be any of a square hole, a circular hole, and a polygonal hole, which is not limited to the rectangular hole shown in the drawings.

Thus, by providing the plurality of first openings 11 in the first region 10 of the mask and providing the plurality of third openings 21 having the same structure as the first openings 11 along the predetermined direction in the second region 20, the vapor deposition for sub-pixels of at least two colors can be realized by successively moving the mask the predetermined distance L. As such, an undesirable risk such as color mixing can be avoided and the vapor deposition effect of the mask can be improved.

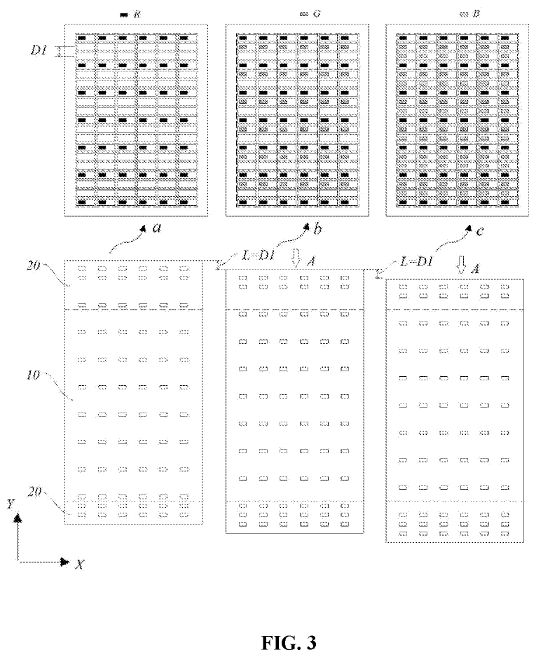

FIG. 3 is a schematic diagram of a moving process of the mask shown in FIG. 2 during vapor deposition for sub-pixels of different colors.

Referring to FIG. 3, an organic material of a color such as the red color is placed in an evaporation chamber in the vapor deposition device, and the first region 10 of the mask is disposed corresponding to the organic light-emitting material layer of the substrate of the OLED display panel. The vapor deposition for red sub-pixels is completed via the plurality of first openings 11 in the first region 10, as shown by arrow a in the figure; then, the mask is moved a distance L=D1 along the direction of arrow A shown in FIG. 3 so that a line of third openings 21 in the second region 20 and the remaining first openings 11 in the first region 10 are collectively disposed corresponding to the organic light-emitting material layer of the substrate, and a green organic material is placed in another evaporation chamber in the vapor deposition device to complete the vapor deposition for the green sub-pixels, as shown by arrow b in the figure; and then, the mask is further moved a distance L=D1 along the direction of arrow A shown in FIG. 3 so that a line of third openings 21 in the second region 20 and the remaining first openings 11 in the first region 10 are collectively disposed corresponding to the organic light-emitting material layer of the substrate, and a blue organic material is placed in another evaporation chamber in the vapor deposition device to complete the vapor deposition for the blue sub-pixels, as shown by arrow c in the figure.

During the vapor deposition process, it is not necessary to repeatedly disassemble the mask, so that impurities such as dust and the like can be prevented from being mixed onto the mask, the effect and efficiency of the vapor deposition can be improved, and the structure is simple and the cost is low.

It can be understood that the vapor deposition process for the sub-pixels of two or more colors is similar to the above-described vapor deposition process for the sub-pixels of three colors, and the order of vapor deposition for multiple colors is also not limited to the examples shown in the drawings, which will not be described again.

### Second Embodiment

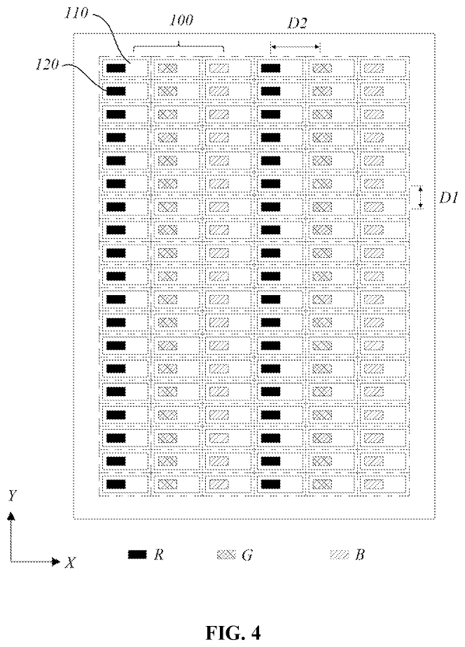

FIG. 4 is a schematic diagram of pixel arrangement of an OLED display panel in the second embodiment.

Referring to FIG. 4, the structure of the OLED display panel is similar to the structure of the OLED display panel shown in FIG. 1, except that each column of sub-pixels 110 along the second direction Y in the OLED display panel have a same color.

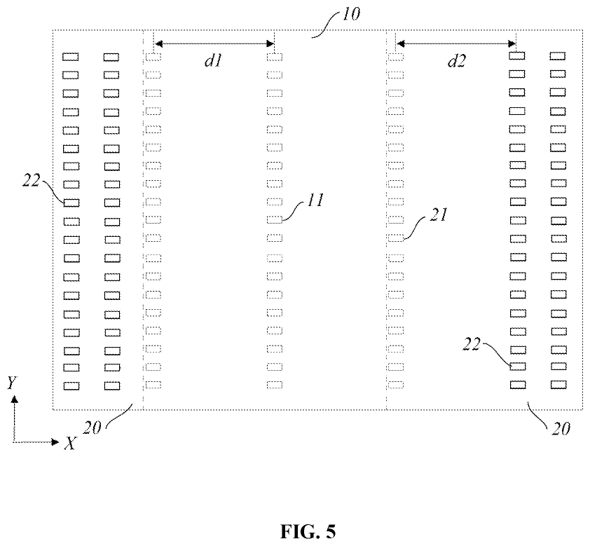

FIG. 5 is a schematic structural diagram of a mask provided in the second embodiment of the application.

Referring to FIG. 5, the mask includes a first region 10 and second regions 20. As shown by the dashed box in FIG. 5, the design principle of the mask is similar to the design principle of the mask shown in FIG. 2, except that the predetermined direction is the first direction X and the second regions 20 are located at both sides of the first region 10 along the first direction X.

The plurality of first openings 11 in the first region 10 and the plurality of third openings 21 in one of the second regions 20 are aligned in rows and columns along the first direction X and the second direction Y, and the plurality of third openings 21 are distributed in a line in the first direction X. In the first region 10 and the second regions 20, a first distance d1 along the first direction X between two adjacent first openings 11, a first distance d1 along the first direction X between two adjacent third openings 21 and a first distance d1 along the first direction X between a first opening 11 and a third opening 21 adjacent to the first opening 11 all satisfy d1=3×D2, and a second distance d2 along the first direction X between a third opening 21 and an adjacent second opening 22 in one of the second regions 20 satisfies d2≥d1, so that the vapor deposition for the sub-pixels of at least two colors can be realized.

For the OLED display panels of the same size shown in FIG. 1 and FIG. 4, the area of the mask shown in FIG. 5 is larger than the area of the mask shown in FIG. 2, and accordingly the size of the vapor deposition device will also be larger.

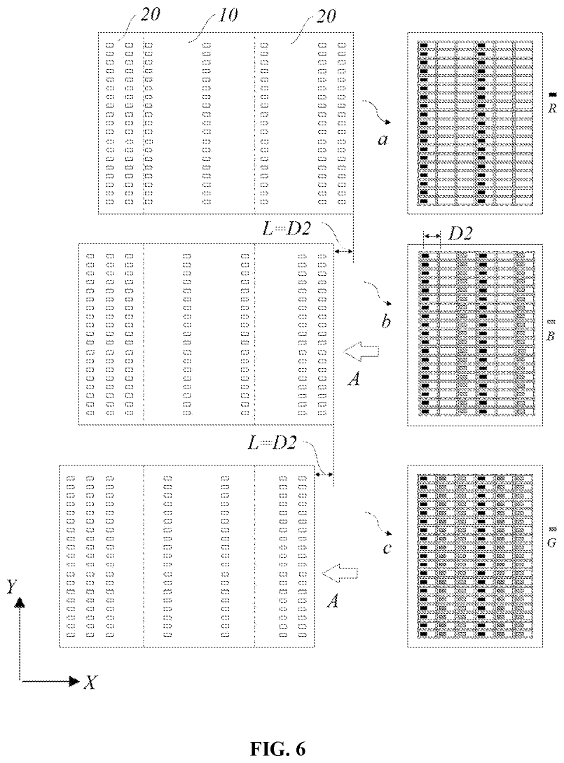

FIG. 6 is a schematic diagram of a moving process of the mask shown in FIG. 5 during vapor deposition for sub-pixels of different colors.

Referring to FIG. 6, an organic material of a color such as the red color is placed in an evaporation chamber in the vapor deposition device, and the first region 10 of the mask is disposed corresponding to the organic light-emitting material layer of the substrate of the OLED display panel. The vapor deposition for red sub-pixels is completed via the plurality of first openings 11 in the first region 10, as shown by arrow a in the figure; then, the mask is moved a distance L=D2 along the direction of arrow A shown in FIG. 3 so that a line of third openings 21 in the second region 20 and the remaining first openings 11 in the first region 10 are collectively disposed corresponding to the organic light-emitting material layer of the substrate, and a blue organic material is placed in another evaporation chamber in the vapor deposition device to complete the vapor deposition for the blue sub-pixels, as shown by arrow b in the figure; and then, the mask is further moved a distance L=D2 along the direction of arrow A shown in FIG. 3 so that a line of third openings 21 in the second region 20 and the remaining first openings 11 in the first region 10 are collectively disposed corresponding to the organic light-emitting material layer of the substrate, and a green organic material is placed in another evaporation chamber in the vapor deposition device to complete the vapor deposition for the green sub-pixels, as shown by arrow c in the figure.

It can be understood that the vapor deposition process for the sub-pixels of two or more colors is similar to the above-described vapor deposition process for the sub-pixels of three colors, and the order of vapor deposition for multiple colors is also not limited to the examples shown in the drawings, which will not be described again.

### Third Embodiment

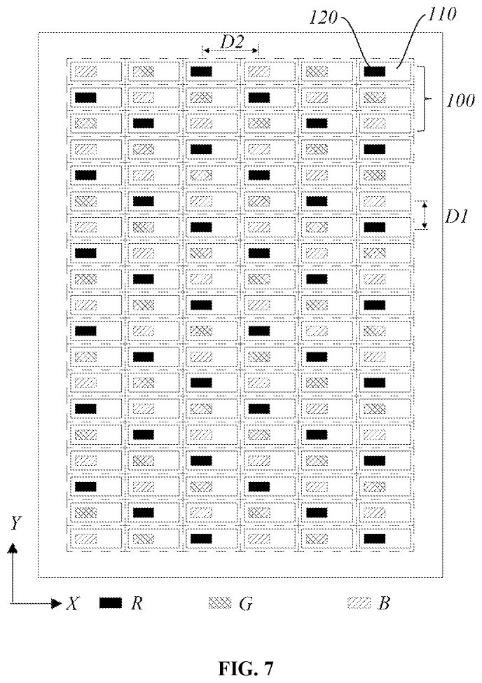

FIG. 7 is a schematic diagram of pixel arrangement of an OLED display panel in the third embodiment of the application.

Referring to FIG. 7, the structure of the OLED display panel is similar to the structure of the OLED display panel shown in FIG. 1, except that color sub-pixels 110 of a same color among adjacent N lines of color sub-pixels 110 in the OLED display panel are sequentially staggered.

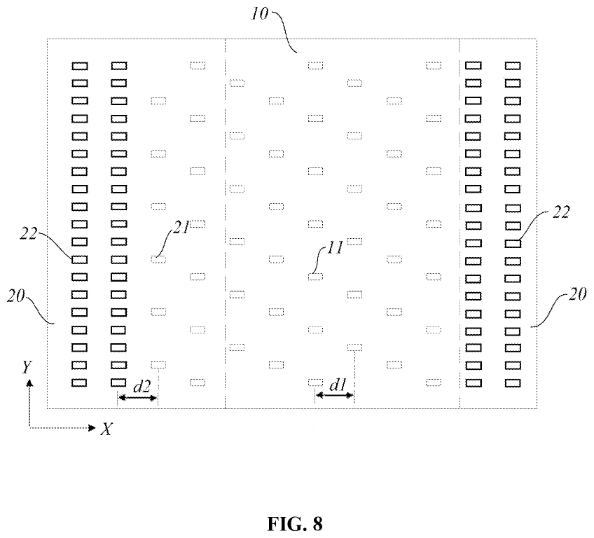

FIG. 8 is a schematic structural diagram of the mask provided in the third embodiment of the application.

Referring to FIG. 8, in the first region 10 and the second regions 20 of the mask, the plurality of first openings 11 and the plurality of third openings 21 are arranged in lines along a direction at a predetermined angle from the predetermined direction, for example, along a direction at an acute angle of 45°, and the plurality of third openings 21 are arranged in M lines, where M is an integer and M≥N−1, and N is the number of types of the sub-pixels to be formed. As such, the plurality of first openings 11 in the first region 10 are disposed respectively corresponding to sub-pixels of any color of the plurality of groups of light-emitting pixel elements shown in FIG. 7, so as to form the sub-pixels of any color, such as red sub-pixels.

The second regions 20 are located at both sides of the first region 10 along the predetermined direction. At least one of the second regions 20 is provided with the plurality of third openings 21. The first openings 11 and the third openings 21 are adjacent to each other and have a same structure, so that the vapor deposition for the sub-pixels of at least two colors can be completed by moving the mask the predetermined distance along the predetermined direction.

Further, in the first region 10 and the second regions 20, a first distance d1 along the predetermined direction between two adjacent first openings 11, a first distance d1 along the predetermined direction between two adjacent third openings 21 and a first distance d1 along the predetermined direction between a first opening 11 and an third opening 21 adjacent to the first opening 11 all satisfy Equation (2):

d1=L (2)

Here, L is the predetermined distance the mask moves along the predetermined direction. When the predetermined direction is the second direction Y, L is the distance D1 along the second direction Y between two adjacent sub-pixels 110; when the predetermined direction is the first direction X, L is the distance D2 along the first direction X between two adjacent sub-pixels 110.

In FIG. 8, the predetermined direction is the first direction X, and the second regions 20 are located at both sides of the first region 10 along the first direction X. Along a direction at an acute angle from the predetermined direction, the plurality of first openings 11 and the plurality of third openings 21 are arranged in lines, and the plurality of third openings 21 are arranged in two lines. That is, the plurality of first openings 11 in the first region 10 and the plurality of third openings 21 in one of the second regions 20 are staggered in each adjacent three lines and extended along the first direction X with each adjacent three lines as a period, and the plurality of third openings 21 are distributed in two lines in the first direction X. In the first region 10 and the second regions 20, a first distance d1 along the first direction X between two adjacent first openings 11, a first distance d1 along the first direction X between two adjacent third openings 21, and a first distance d1 along the first direction X between a first opening 11 and a third opening 21 adjacent to the first opening 11 all satisfy d1=D2.

The second regions 20 serve as a process buffer for the first region 10, and each second region 20 is further provided with second openings 22 aligned in rows and columns along the first direction X and the second direction Y. The second openings 22 in at least one second region 20 are disposed at a side of the plurality of corresponding third openings 21 along the predetermined direction. There are at least two lines of second openings 22 in each second region 20, and the machining accuracy of the second openings 22 is lower than the machining accuracy of the first openings 11. The shapes and sizes of the second openings 22 may be the same as or different from the shapes and sizes of the first openings 11.

In addition, when the plurality of third openings 21 are arranged in two lines, an overall size of the mask is minimal. In order to complete the vapor deposition for multi-color sub-pixels, in the second region 20, a second distance d2 along the predetermined direction between a third opening 21 and a second opening 22 adjacent to the third opening 21 satisfies d2≥d1.

Further, the shape of the first opening 11 corresponds to the shape of the organic light emitting material layer 120 of the sub-pixel 110, and the size of the first opening 11 is larger than the size of the organic light emitting material layer 120. In addition, the shape of the first opening 11 may be any of a square hole, a circular hole, and a polygonal hole, which is not limited to the rectangular hole shown in the drawings.

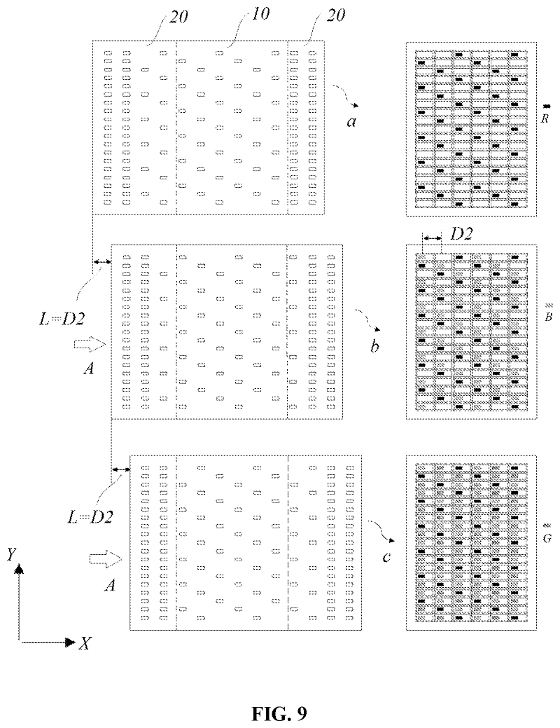

FIG. 9 is a schematic diagram of a moving process of the mask shown in FIG. 8 during vapor deposition for sub-pixels of different colors.

Referring to FIG. 9, an organic material of a color such as the red color is placed in an evaporation chamber in the vapor deposition device, and the first region 10 of the mask is disposed corresponding to the organic light-emitting material layer of the substrate of the OLED display panel. The vapor deposition for red sub-pixels is completed via the plurality of first openings 11 in the first region 10, as shown by arrow a in the figure; then, the mask is moved a distance L=D2 along the direction of arrow A shown in FIG. 3 so that a line of third openings 21 in the second region 20 and the remaining first openings 11 in the first region 10 are collectively disposed corresponding to the organic light-emitting material layer of the substrate, and a blue organic material is placed in another evaporation chamber in the vapor deposition device to complete the vapor deposition for the blue sub-pixels, as shown by arrow b in the figure; and then, the mask is further moved a distance L=D2 along the direction of arrow A shown in FIG. 3 so that two lines of third openings 21 in the second region 20 and the remaining first openings 11 in the first region 10 are collectively disposed corresponding to the organic light-emitting material layer of the substrate, and a green organic material is placed in another evaporation chamber in the vapor deposition device to complete the vapor deposition for the green sub-pixels, as shown by arrow c in the figure.

It can be understood that the vapor deposition process for the sub-pixels of two or more colors is similar to the above-described vapor deposition process for the sub-pixels of three colors, and the order of vapor deposition for multiple colors is also not limited to the examples shown in the drawings, which will not be described again.

### Fourth Embodiment

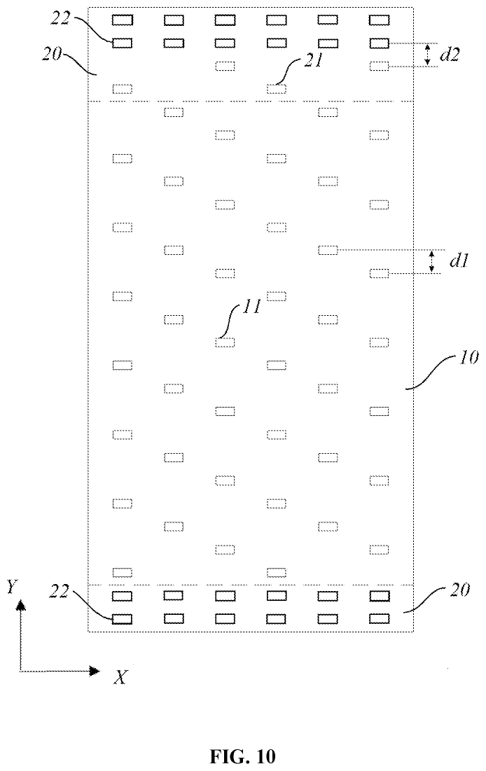

FIG. 10 is a schematic structural diagram of a mask provided in the fourth embodiment of the application.

Referring to FIG. 10, the mask includes a first region 10 and second regions 20. As shown by the dashed box in FIG. 10, the design principle of the mask is similar to that of the mask shown in FIG. 8, except that the predetermined direction is the second direction Y and the second regions 20 are located at both sides of the first region 10 along the second direction Y. The plurality of third openings 21 are distributed in two lines in the second direction Y. In the first region 10 and the second regions 20, a first distance d1 along the second direction Y between two adjacent first openings 11, a first distance d1 along the second direction Y between two adjacent third openings 21 and a first distance d1 along the second direction Y between a first opening 11 and a third opening 21 adjacent to the first opening 11 all satisfy d1=D1, and a second distance d2 along the second direction Y between a third opening 21 and a second opening 22 adjacent to the third opening 21 in one of the second regions 20 satisfies d2≥d1, so that the vapor deposition for the sub-pixels of at least two colors can be realized.

For the same OLED display panel as shown in FIG. 7, the area of the mask shown in FIG. 10 is smaller than the area of the mask shown in FIG. 8, and accordingly the size of the vapor deposition device will also be smaller, so it may be preferable to use the mask shown in FIG. 10.

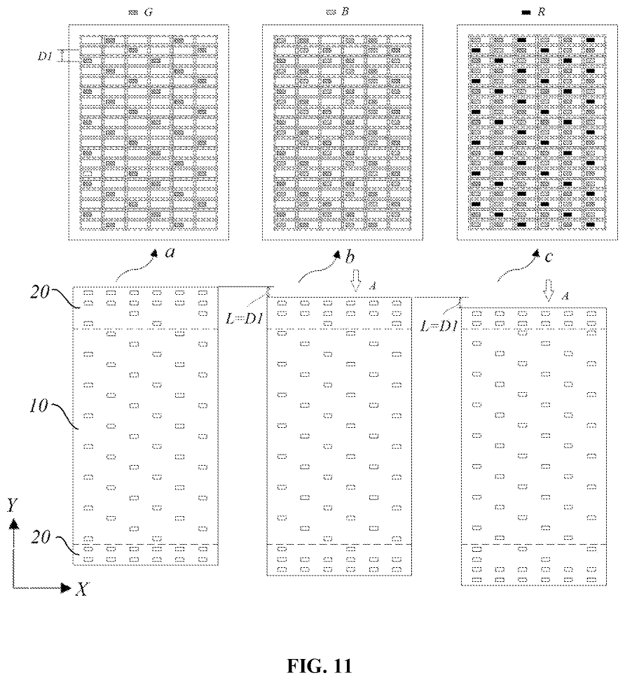

FIG. 11 is a schematic diagram of a moving process of the mask shown in FIG. 10 during vapor deposition for sub-pixels of different colors.

Referring to FIG. 11, an organic material of a color such as the green color is placed in an evaporation chamber in the vapor deposition device, and the first region 10 of the mask is disposed corresponding to the organic light-emitting material layer of the substrate of the OLED display panel. The vapor deposition for green sub-pixels is completed via the plurality of first openings 11 in the first region 10, as shown by arrow a in the figure; then, the mask is moved a distance L=D1 along the direction of arrow A shown in FIG. 3 so that a line of third openings 21 in the second region 20 and the remaining first openings 11 in the first region 10 are collectively disposed corresponding to the organic light-emitting material layer of the substrate, and a blue organic material is placed in another evaporation chamber in the vapor deposition device to complete the vapor deposition for the blue sub-pixels, as shown by arrow b in the figure; and then, the mask is further moved a distance L=D1 along the direction of arrow A shown in FIG. 3 so that two lines of third openings 21 in the second region 20 and the remaining first openings 11 in the first region 10 are collectively disposed corresponding to the organic light-emitting material layer of the substrate, and a red organic material is placed in another evaporation chamber in the vapor deposition device to complete the vapor deposition for the red sub-pixels, as shown by arrow c in the figure.

It can be understood that the vapor deposition process for the sub-pixels of two or more colors is similar to the above-described vapor deposition process for the sub-pixels of three colors, and the order of vapor deposition for multiple colors is also not limited to the examples shown in the drawings, which will not be described again.

Therefore, by use of the mask provided in the embodiments of the application, for both an OLED display panel in which sub-pixels 110 of a same color are distributed in a same line and an OLED display panel in which color sub-pixels 110 of a same color among adjacent N lines of color sub-pixels 110 are sequentially staggered, third openings 21 can be disposed at both sides of the first region 10 of the mask along the first direction X or the second direction Y, so that the vapor deposition for sub-pixels of at least two colors can be realized by moving the mask a predetermined distance.

In addition, since a distance along the second direction Y between two adjacent color sub-pixels is smaller than a distance along the first direction X between two adjacent color sub-pixels in the OLED display panel, the area of the mask in which the third openings 21 are disposed at both sides of the first region 10 along the second direction Y is smaller compared to the area of the mask in which the third openings 21 are disposed at both sides of the first region 10 along the first direction X, and the size of the corresponding evaporation device is also smaller. The mask may be selected according to specific pixel arrangements in different OLED display panels.

In addition, an embodiment of the application further provides a vapor deposition device including any mask described above.

Those skilled in the art should understand that the above-described embodiments are all exemplary and not restrictive. Different technical features appearing in different embodiments can be combined to obtain beneficial effects. Those skilled in the art should be able to understand and implement other modified embodiments of the disclosed embodiments on the basis of studying the drawings, the description, and the claims. In the claims, the term “comprising” does not exclude other devices or steps; the indefinite article “a” does not exclude a plurality; the terms “first”, “second”, “third”, “fourth” and the like are used to illustrate names rather than to indicate any particular order. Any reference numerals in the claims should not be construed as limiting the scope of protection. The functions of the various parts in the claims may be implemented by a single hardware or software module. The presence of certain features in different dependent claims does not indicate that these technical features cannot be combined to achieve beneficial effects.

1. A mask comprising:
a first region provided with a first plurality of openings; and
second regions located at both sides of the first region along a predetermined direction, wherein at least one of the second regions is provided with a third plurality of openings, and the third plurality of openings are disposed adjacent to the first plurality of openings and characterized by a same structure as the first plurality of openings;
wherein:
at least a part of the first plurality of openings are used to form a first type of sub-pixels when the mask is in a first state, and
the first plurality of openings and at least a part of the third plurality of openings are used together to form a type of sub-pixels different from the first type of sub-pixels, when the mask moves a predetermined distance along the predetermined direction to be in a second state.

2. The mask according to claim 1, wherein, the third plurality of openings are arranged in a same manner as an arrangement of the first plurality of openings, and the third plurality of openings are arranged in M lines along a direction at a predetermined angle from the predetermined direction, where M is an integer and M≥1.

3. The mask according to claim 2, wherein, the first plurality of openings and the third plurality of openings are arranged in lines along a direction perpendicular to the predetermined direction, and in the first region and the second regions, a first distance d1 along the predetermined direction between two adjacent openings of the first plurality of openings, a first distance d1 along the predetermined direction between two adjacent openings of the third plurality of openings, and a first distance d1 along the predetermined direction between a first opening of the first plurality of openings and a second opening of the third plurality of openings adjacent to the first opening all satisfy an equation (1):
d1=N× L (1)
wherein, L is the predetermined distance the mask moves along the predetermined direction, and N is the number of types of sub-pixels to be formed.

4. The mask according to claim 1, wherein, along a direction at a predetermined angle from the predetermined direction, the first plurality of openings and the third plurality of openings are arranged in lines, and the third plurality of openings are arranged in M lines, where M is an integer and M≥N−1, and N is the number of types of sub-pixels to be formed.

5. The mask according to claim 4, wherein, in the first region and the second regions, a first distance d1 along the predetermined direction between two adjacent openings of the first plurality of openings, a first distance d1 along the predetermined direction between two adjacent openings of the third plurality of openings and a first distance d1 along the predetermined direction between a first opening of the first plurality of openings and a second opening of the third plurality of openings adjacent to the first opening all satisfy an equation (2):
d1=L (2)
wherein, L is the predetermined distance the mask moves along the predetermined direction.

6. The mask according to claim 1, wherein, the second regions are provided with a second plurality of openings, and in at least one of the second regions, the second plurality of openings are disposed at a side of the third plurality of openings corresponding to the second plurality of openings along the predetermined direction.

7. The mask according to claim 3, wherein, the second regions are provided with a second plurality of openings, and in at least one of the second regions, the second plurality of openings are disposed at a side of the third plurality of openings corresponding to the second plurality of openings along the predetermined direction.

8. The mask according to claim 7, wherein, in the second regions, a second distance d2 along the predetermined direction between a third opening of the third plurality of openings and a fourth opening of the second plurality of openings adjacent to the third opening satisfies an equation (3):
d2≥d1 (3).

9. The mask according to claim 8, wherein, in the second regions, the number of the second openings is more than one, and the second plurality of openings are arranged in at least two lines.

10. The mask according to claim 6, wherein, three types of sub-pixels are to be formed, the predetermined direction is a second direction, a first direction is perpendicular to the second direction, the first plurality of openings in the first region and the third plurality of openings in one of the second regions are aligned in rows and columns along the first direction and the second direction, and the third plurality of openings are distributed in a line in the second direction; and
in at least one of the second regions, the second plurality of openings are disposed at a side of the third plurality of openings corresponding to the second plurality of openings along the second direction.

11. The mask according to claim 6, wherein, three types of sub-pixels are to be formed, the predetermined direction is a first direction, the first direction is perpendicular to a second direction, the first plurality of openings in the first region and the third plurality of openings in one of the second regions are staggered in each adjacent three lines and extended along the first direction with each adjacent three lines as a period, and the third plurality of openings are distributed in two lines in the first direction; and
in at least one of the second regions, the second plurality of openings are disposed at a side of the third plurality of openings corresponding to the second plurality of openings along the first direction.

12. The mask according to claim 1, wherein, a shape of a first opening of the first plurality of openings is any of a square hole, a round hole, and a polygonal hole.

13. A vapor deposition device comprising the mask according to claim 1.

14. A vapor deposition method by use of a mask, wherein the mask comprises a first region provided with a first plurality of openings and second regions located at both sides of the first region along a predetermined direction, at least one of the second regions is provided with a third plurality of openings, and the third plurality of openings are disposed adjacent to the first plurality of openings and have a same structure as the first plurality of openings, wherein the vapor deposition method comprises:
forming a first type of sub-pixels by use of at least a part of the first plurality of openings when the mask is in a first state;
moving the mask a predetermined distance along the predetermined direction to place the mask in a second state; and
forming a type of sub-pixels different from the first type of sub-pixels by use of the first plurality of openings and at least a part of the third plurality of openings together when the mask is in the second state.

15. The vapor deposition method according to claim 14, wherein, the third plurality of openings are arranged in a same manner as an arrangement of the first plurality of openings, and the third plurality of openings are arranged in M lines along a direction at a predetermined angle from the predetermined direction, where M is an integer and M≥1.

16. The vapor deposition method according to claim 15, wherein, the first plurality of openings and the third plurality of openings are arranged in lines along a direction perpendicular to the predetermined direction, and in the first region and the second regions, a first distance d1 along the predetermined direction between two adjacent openings of the first plurality of openings, a first distance d1 along the predetermined direction between two adjacent openings of the third plurality of openings, and a first distance d1 along the predetermined direction between a first opening of the first plurality of openings and a second opening of the third plurality of openings adjacent to the first opening all satisfy an equation (1):
d1=N×L (1)
wherein, L is the predetermined distance the mask moves along the predetermined direction, and N is the number of types of sub-pixels to be formed.

17. The vapor deposition method according to claim 14, wherein, along a direction at a predetermined angle from the predetermined direction, the first plurality of openings and the third plurality of openings are arranged in lines, and the third plurality of openings are arranged in M lines, where M is an integer and M≥N−1, and N is the number of types of sub-pixels to be formed.

18. The vapor deposition method according to claim 17, wherein, in the first region and the second regions, a first distance d1 along the predetermined direction between two adjacent openings of the first plurality of openings, a first distance d1 along the predetermined direction between two adjacent openings of the third plurality of openings and a first distance d1 along the predetermined direction between a first opening of the first plurality of openings and a second opening of the third plurality of openings adjacent to the first opening all satisfy an equation (2):
d1=L (2)
wherein, L is the predetermined distance the mask moves along the predetermined direction.

19. The vapor deposition method according to claim 16, wherein, the second regions are provided with a second plurality of openings, and in at least one of the second regions, the second plurality of openings are disposed at a side of the third plurality of openings corresponding to the second plurality of openings along the predetermined direction.

20. The vapor deposition method according to claim 19, wherein, in the second regions, a second distance d2 along the predetermined direction between a third opening of the third plurality of openings and a fourth opening of the second plurality of openings adjacent to the third opening satisfies an equation (3):
d2≥d1 (3).
